(19) United States
(12) Patent Application Publication
(10) Pub. No.: US 2022/0272830 A1
(43) Pub. Date: Aug. 25, 2022

(54) FLEXIBLE TRANSPARENT COPPER CIRCUIT, PREPARATION METHOD THEREFOR, AND APPLICATION THEREOF

(71) Applicant: South China University of Technology, Guangzhou City (CN)

(72) Inventors: Liang Liang, Guangzhou City (CN); Changcheng Jiang, Guangzhou City (CN)

(21) Appl. No.: 17/629,031

(22) PCT Filed: Jul. 22, 2020
(86) PCT No.: PCT/CN2020/103504

§ 371 Date: Jan. 21, 2022

(30) Foreign Application Priority Data
Jul. 23, 2019 (CN) 201910666303.X

(51) Int. Cl. H05K 1/02; H01B 13/00; H05K 3/46

(52) U.S. Cl. CPC H05K 1/028; H01B 13/0026; H05K 3/4691; H05K 2203/107

(57) ABSTRACT

A flexible transparent copper circuit, a preparation method therefor, and a application thereof. The preparation method specifically comprises the following steps: (1) uniformly coating a gel containing copper powder on one side of a glass sheet, and drying same to form a copper film layer; and (2) placing the one side of the glass sheet coated with the copper film layer opposite to a polymer material, scanning the other side using a laser beam such that the copper film layer is transferred to a suropposite to of the polymer material, and performing post-processing to obtain a flexible transparent copper circuit. The copper circuit obtained by the preparation method has good potential in flexible photovoltaic applications. Moreover, since laser processing has fast speed and inherent flexibility, the transferred metal circuit can be freely designed, thus improving the processing efficiency and facilitating mass production.

### TECHNICAL FIELD

The present invention belongs to the technical field of material processing, and particularly relates to a flexible transparent copper circuit, and a preparation method therefor and an application thereof.

### BACKGROUND

Transparent conductors, such as indium tin oxide (ITO), gallium-doped zinc oxide (GZO), and poly(styrene sulfonate), play a central role in the development of touch display computing. At the same time, wearable devices, photovoltaics, and other bendable photovoltaic film technologies require robust electronic interfaces with high light transmittance. However, in the technology to successfully integrate these devices into the “soft matter” of future wearable devices, e.g. a man-machine interface, bionic contact, or a direct interface between living neurons and resistance switchgears, a new generation of “optically transparent” conductors are needed to prepare transparent materials that match the mechanical properties of soft biological tissues. The work in this field mainly focuses on two fields: a synthetic composite material (e.g. an elastomer with a conductive nano-filler), and a multifunctional material, i.e. a material formed by combining a high-performance conductive material with a stretchable polymer (the elastomer having a patterned metal film on the substrate).

The first kind of material includes microgels invisible to the naked eye such as carbon nanotubes, graphene, metal nanowires, or metal salts, which are obtained by loading transparent elastic polyethylene into various stretchable conductive materials. This kind of material has certain stretchability, low electrical resistance and high optical transparency, and exhibits important electromechanical, optomechanical coupling and hysteresis properties. However, this kind of material realizes the transfer of graphene and carbon nanotubes mainly through an acid solution, thus causing great damage to the environment. The second kind of material is obtained by preparing a patterned grid substrate of gold or copper on a soft polymer substrate. The balance relation between the electrical resistance and the light transmittance of this material can be adjusted by the thickness of the conductive material and the spatial distance between the visible opaque features. However, the structures of these multifunctional materials exhibit poor stretchability, mechanical failure is prone to occur due to the out-of-plane deformation of the non-stretchable metal grid, and the metal pattern cannot be designed independently and lacks flexibility. In summary, these technologies are currently limited to laboratory tests and experiments, and cannot meet the requirements of industrial applications.

### SUMMARY

In order to overcome the above-described shortcomings and deficiencies of the prior art, a primary object of the present invention is to provide a method for preparing a flexible transparent copper circuit.

Another object of the present invention is to provide a flexible transparent copper circuit prepared by the above-described method.

Still another object of the present invention is to provide an application of the above-mentioned flexible transparent copper circuit in an optically transparent conductor.

The objects of the present invention are achieved by the following solution. A method for preparing a flexible transparent copper circuit is provided, specifically comprising the following steps:

(1) coating a gel containing copper powder uniformly to one side of a glass sheet, and then drying to form a copper film layer; and

(2) placing the one side of the glass sheet coated with the copper film layer obtained in the step (1) opposite to a polymer material, then scanning the other side of the glass sheet with a laser beam to transfer the copper film layer to the surface of the polymer material, and performing post-processing to obtain a flexible transparent copper circuit.

The gel containing copper powder in the step (1) is prepared by mixing diglycidyl polyethylene glycol (EO-PEG-EO) gel and simple substance copper powder for 10-40 min, preferably on a mechanical mixer for powder; and the solid content of the copper powder in the gel containing copper powder is 0.89-1.34 g/cm³.

Preferably, a preparation process of the EO-PEG-EO gel is:

The ratio of the amount of the gel containing copper powder to the area of the glass sheet in the step (1) is 2-3 g/m².

The coating in the step (1) is dropping the gel containing copper powder onto the glass sheet and then centrifuging the sheet at a rate of 800-1500 rpm for 1-10 min, preferably at a rate of 1000 rpm for 4 min.

The drying in the step (1) is drying the glass sheet coated with the gel containing copper powder in a drying oven for 1-5 h, preferably 2 h.

The polymer material in the step (2) is one of polyethylene terephthalate, low-density polyethylene, high-density polyethylene, and polyvinyl chloride resin, etc.

The distance between the copper film layer and the polymer material in the step (2) is 3-5 mm.

The laser beam in the step (2) has an output power of 4-6 W, a scanning speed of 500-800 mm/s, and a frequency of 20-50 kHz.

The post-processing in the step (2) is washing the obtained polymer material in acetone for 10-20 min to remove the gel from the copper circuit.

A flexible transparent copper circuit prepared by the above-described method is provided.

An application of the above-mentioned flexible transparent copper circuit in an optically transparent conductor is provided.

The optically transparent conductor is an electrode of a solar cell, or a flexible transparent display device.

The mechanism of the present invention is as follows: In the present invention, the copper film layer can be transferred to the surface of the polymer material by a laser beam that can penetrate the glass sheet, and the copper film layer on the substrate can realize a sub-micron-sized thickness while maintaining good conductivity. The copper powders of the copper film layer of the obtained flexible transparent circuit do not combine with the substrate through chemical bonds, therefore, when the circuit is bent, the powders in the copper circuit can slip between layers to avoid fracture.

Compared with the prior art, the present invention has the following advantages and beneficial effects:

The present invention adopts the laser plasma-driven micromachining technology to transfer the copper film to the transparent substrate to obtain a transparent, stretchable and highly flexible copper film circuit. These films consist of a grid-like array of metal copper wires on a transparent elastomer. Wherein, the metal circuits prepared side by side on a flexible polyethylene terephthalate substrate exhibit excellent performance at a condition of being bent to up to 138°, while the ITO-based devices show cracks and irreversible failures at a condition of being bent at 60°, indicating that the copper films have great potential in application in flexible photovoltaic cells. At the same time, due to the high speed, simplicity and inherent flexibility of the laser processing, the transferred metal circuit can be freely designed, and the processing efficiency is higher, allowing large-scale production.

### BRIEF DESCRIPTION OF THE DRAWINGS

FIG. 1 is a flow chart for a test of the present invention.

FIG. 2 is a three-dimensional atomic force microscope image of a single copper circuit obtained in Example 1.

FIG. 3 is a two-dimensional atomic force microscope image of copper circuits with different grid sizes obtained in Example 1, wherein the side lengths in Figs. (a), (b), (c) and (d) are 200 μm, 300 μm, 400 μm and 500 μm, respectively.

FIG. 4 is a graph of the light transmittances of the flexible transparent copper circuits with different grid sizes obtained in Example 1 and ITO.

FIG. 5 is diagrams of a bending test conducting on and an experimental device for the copper circuit obtained in Example 1, wherein Fig. (a) is a cyclic bending test device, Fig. (b) is the photo of the flexible transparent copper circuit upon bending deformation, and Fig. (c) is the photo of the flexible transparent copper circuit upon the maximum bending deformation.

FIG. 6 is graphs of the characters of current density with voltage of the flexible transparent copper circuit with a grid side length of 400 μm obtained in Example 1 and the ITO photovoltaic cell at different bending angles, wherein Fig. (a) is the flexible transparent copper circuit, and Fig. (b) is the ITO photovoltaic cell.

### DETAILED DESCRIPTION OF THE EMBODIMENTS

The present invention will be further described in detail below with reference to examples and the drawings, but the embodiments of the present invention are not limited thereto.

The reagents used in the examples can be routinely purchased from the market, unless otherwise specified.

In this example, for the characterization test steps, reference is made to the following literature: Pan C, Kumar K, Li J, et al. Visually Imperceptible Liquid-Metal Circuits for Transparent, Stretchable Electronics with Direct Laser Writing [J]. Advanced Materials, 2018, 30(12): 1706937.

### Example 1

This example shows a method for preparing a flexible transparent copper circuit, which comprises the following steps:

(1) selecting a polyethylene terephthalate film (2 mm thick) and a glass sheet (1 mm thick) as the substrate of a circuit; first washing the substrate with a deionized water, then putting the substrate material and the glass sheet into a beaker filled with anhydrous alcohol to wash in an ultrasonic instrument for 20 min, and finally blowing dry with high-purity helium gas and drying in a drying oven for 20 min;

(2) mixing polyethylene glycol gel with an average molecular weight of 6000 and simple substance copper powder by means of mechanical mixing, and then mechanically mixing the obtained mixture on a mechanical mixer for powder for 30 min to obtain a uniformly mixed gel containing copper powder at a solid content of 1.0 g/cm³;

(3) dropping the gel containing copper powder onto the glass sheet obtained in the step (1) at a dosage of 2.5 g/m², coating the same on the glass sheet, and then centrifuging the glass sheet in a high-speed centrifuge at 1000 rpm for 4 min to obtain the glass sheet with the surface evenly coated with the gel (at a thickness of the gel layer of about 20 μm), with the substrate of the glass sheet and polyethylene glycol having a radius of 3 cm;

(4) placing the one side of the glass sheet coated with the copper film layer opposite to the substrate, and then using a laser beam to scan the uncoated side of the glass sheet with parameters of the laser beam being at a scanning speed of 600 mm/s, a power of 5 W, and a frequency of 30 kHz; transferring the copper film layer to the surface of the substrate material directly according to the designed pattern by a laser beam emitted from a laser light source with a wavelength of 355 nm, a pulse width of 7 ns and a spot size of 8 μm, to obtain copper circuits of different grid sizes with a thickness of about 2 μm on the substrate; and

(5) washing the transferred copper circuit obtained in the step (4) in acetone for 15 min to remove the gel in the copper circuit, thus obtaining a flexible transparent copper circuit.

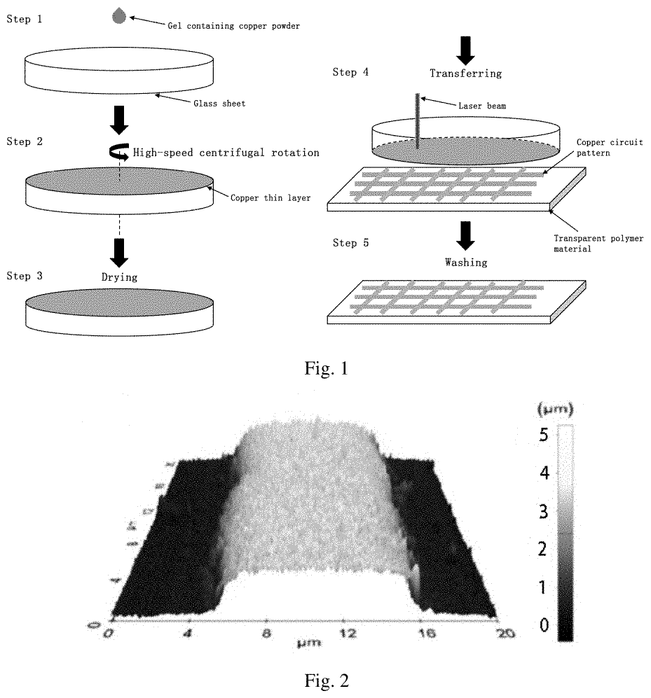

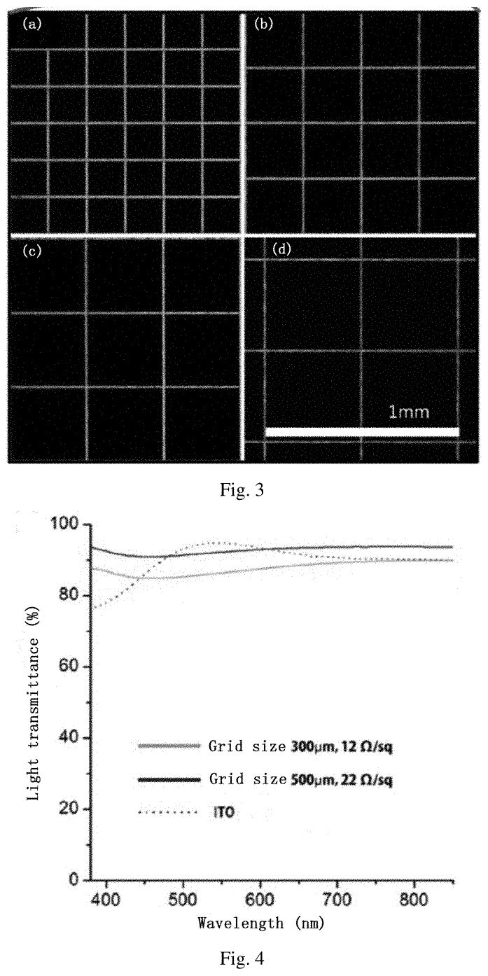

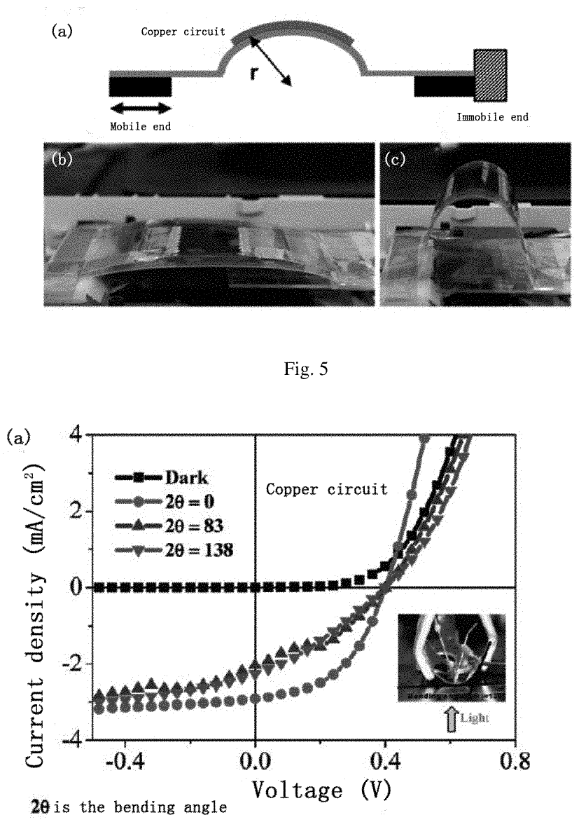

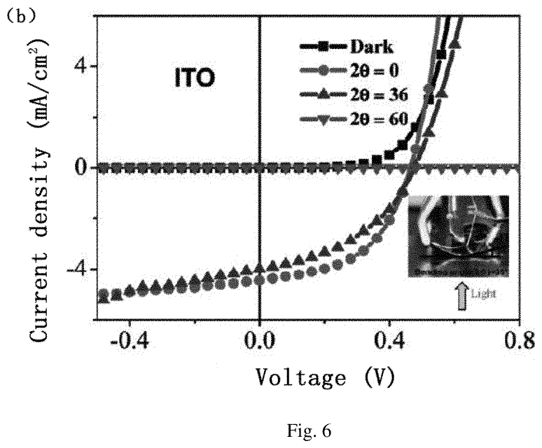

FIG. 2 is an image for atomic force microscope of a single copper circuit obtained in Example 1. FIG. 3 is the copper circuits with different grid sizes obtained in Example 1. The light transmittances of the flexible transparent copper circuit obtained in the present invention and ordinary ITO are characterized, and FIG. 4 is the light transmittances of the copper circuits with different grid sizes obtained in Example 1 and ITO. It can be seen from FIG. 4 that the light transmittance of the metal grid prepared by the present invention is higher than that of the ITO-based transparent conductor, the effect is better especially for the ultraviolet band region. Simultaneously, the present invention can change the light transmittance by adjusting the size of the grid. FIG. 5 is diagrams of a bending test conducting on and an experimental device for the flexible transparent copper circuit obtained in Example 1. FIG. 6 is graphs of the characters of current density with voltage of the copper circuit obtained in Example 1 and the ITO photovoltaic cell at different bending angles. It can be seen from the figure, that the copper circuits obtained in the present invention exhibit excellent performance at a condition of being bent to up to 138°, while the ITO-based devices show cracks and irreversible failures at a condition of being bent at 60°, indicating that the copper films have great potential in application in flexible photovoltaic cells.

The above examples are preferred embodiments of the present invention, but the embodiments of the present invention are not limited thereto, and any other alterations, modifications, replacements, combinations and simplifications shall be equivalent substitutions and fall within the scope of protection of the present invention.

It is claimed:

1. A method for preparing a flexible transparent copper circuit, characterized in that, this :method specifically comprises the following steps:
(1) coating a gel containing copper powder uniformly to one side of a glass sheet, and then drying to form a copper film layer; and
(2) placing the one side of the glass sheet coated with the copper film layer obtained in the step (1) opposite to a polymer material, then scanning an other side of the glass sheet with a laser beam to transfer the copper film layer to a surface of the polymer material, and performing a post-processing to obtain a flexible transparent copper circuit;
the gel containing copper powder in the step (1) is prepared by mixing polyethylene glycol gel and a simple substance copper powder for 10-40 min;
the polymer material in the step (2) is one of polyethylene terephthalate, low-density polyethylene, high-density polyethylene, and polyvinyl chloride resin; and
the post-processing in the step (2) is washing the obtained glass sheet covered with the copper film layer in acetone for 10-20 min to remove the gel from the copper circuit.

2. The method for preparing the flexible transparent copper circuit according to claim 1, characterized in that:
a solid content of the copper powder in the gel containing copper powder in the step (1) is 0.89-1.34 g/cm³.

3. The method for preparing the flexible transparent copper circuit according to claim 1, characterized in that:
a ratio of an amount of the gel containing copper powder to an area of the glass sheet in the step (1) is 2-3 g/m².

4. The method for preparing the flexible transparent copper circuit according to claim 1, characterized in that:
a distance between the copper film layer and the polymer material in the step (2) is 3-5 mm.

5. The method for preparing the flexible transparent copper circuit according to claim 1, characterized in that:
the laser beam in the step (2) has an output power of 4-6 W, a scanning speed of 500-800 mm/s, and a frequency of 20-50 kHz.

6. The method for preparing the flexible transparent copper circuit according to claim 1, characterized in that:
the coating in the step (1) is dropping the gel containing copper powder onto the glass sheet and then centrifuging the sheet at a rate of 800-1500 rpm for 1-10 min.

7. A flexible transparent copper circuit prepared by a method comprising the following steps:
(1) coating a gel containing copper powder uniformly to one side of a glass sheet, and then drying to form a copper film layer; and
(2) placing the one side of the glass sheet coated with the copper film layer obtained in the step (1) opposite to a polymer material, then scanning the other side of the glass sheet with a laser beam to transfer the copper film layer to a surface of the polymer material, and performing a post-processing to obtain a flexible transparent copper circuit;
the gel containing copper powder in the step (1) is prepared by mixing polyethylene glycol gel and a simple substance copper powder for 10-40 min;
the polymer material in the step (2) is one of polyethylene terephthalate, low-density polyethylene, high-density polyethylene, and polyvinyl chloride resin; and
the post-processing in the step (2) is washing the obtained glass sheet covered with the copper film layer in acetone for 10-20 min to remove the gel from the copper circuit.

8. An optically transparent conductor comprising the flexible transparent copper circuit of claim 7.

9. The optically transparent conductor according to claim 8, characterized in that: the optically transparent conductor is an electrode of a solar cell, or a flexible transparent display device.

10. The flexible transparent copper circuit of claim 7, characterized in that:
solid content of a copper powder in the gel containing copper powder in the step (1) is 0.89-1.34 g/cm³.

11. The flexible transparent copper circuit of claim 7, characterized in that:
a ratio of an amount of the gel containing copper powder to the area of the glass sheet in the step (1) is 2-3 g/m².

12. The flexible transparent copper circuit of claim 7, characterized in that:
a distance between the copper film layer and the polymer material in the step (2) is 3-5 mm.

13. The flexible transparent copper circuit of claim 7, characterized in that: the laser beam in the step (2) has an output power of 4-6 W, a scanning speed of 500-800 mm/s, and a frequency of 20-50 kHz.

14. The flexible transparent copper circuit of claim 7, characterized in that:
the coating in the step (1) is dropping the gel containing copper powder onto the glass sheet and then centrifuging the sheet at a rate of 800-1500 rpm for 1-10 min.
